(19) United States
(12) Patent Application Publication
(10) Pub. No.: US 2006/0294279 A1
(43) Pub. Date: Dec. 28, 2006

(54) Mechanism for peripheral component interconnect express (PCIe) connector multiplexing

(76) Inventors: Kenneth G. McKee, Folsom, CA (US); Jeffrey L. Krieger, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/168,607

(22) Filed: Jun. 28, 2005

(51) Int. Cl. H05K 7/10

(52) U.S. Cl. 710/301

(57) ABSTRACT

In one embodiment, an apparatus to enable Peripheral Component Interconnect Express (PCIe) connector multiplexing is presented. The apparatus comprises a continuity module to insert into a first PCIe connector slot and to route a first set of data lanes coupled to the first PCIe connector slot to a second set of data lanes coupled to both of the first PCIe connector slot and a second PCIe connector slot. Other embodiments are also described.

### FIELD OF THE INVENTION

The embodiments of the invention relate generally to the field of computer system platforms and, more specifically, relate to a mechanism to enable Peripheral Component Interconnect Express (PCIe) connector multiplexing.

### BACKGROUND

Chipset implementations presently support more than one Peripheral Component Interconnect Express (PCIe) connector. Currently, chipset implementations may support ×16 functionality with a single PCIe connector, or may support a dual ×8 functionality with two PCIe connectors. However, in order to support both the single ×16 functionality and the dual ×8 functionality, the data lanes between the chipset and PCIe connectors must be routed so as to allow both functionalities on a single platform.

Currently, competitive platform solutions that support dual graphic cards with a bifurcated ×16 chipset add an additional redirection connector with an associated plug-in module onto the platform to control whether one set of ×8 lanes is directed to a second PCIe connector to achieve dual ×8 functionality or is directed back to the first connector to achieve ×16 functionality. Conventional solutions have placed a redirection connector in between PCIe connectors to receive data lanes from the chipset and redirect them to the appropriate PCIe connector.

For example, a first PCIe connector may directly receive eight data lanes from the chipset, while the redirection connector receives the other eight data lanes from the chipset. When the platform is to be operated in dual ×8 mode with two graphic cards, a plug-in module is placed into the redirection connector in one particular orientation (orientation A), which causes it to route its received eight lanes back to a second PCIe connector on the platform. Each PCIe connector has now received ×8 lanes from the chipset, and the other ×8 lanes on each PCIe connector are unused.

When the platform is to be operated in single ×16 mode, the plug-in module is placed into the redirection connector in the opposite orientation (orientation B) which causes it to route its received eight data lanes back to the first PCIe connector on the platform that is also directly receiving the first eight lanes from the chipset. The first PCI connector receives all sixteen data lanes, and the second PCIe connector receives no data lanes and is thus non-operational.

Such a conventional implementation is costly as it requires two new components to be implemented, a redirection connector placed onto the motherboard and a plug-in module for mounting into the redirection connector. The separate redirection connector also takes up valuable space on the motherboard that could be utilized for other purposes and features. A solution that allows for PCIe single and dual card functionality, while utilizing existing platform components, would be a beneficial way to lower costs.

### BRIEF DESCRIPTION OF THE DRAWINGS

The invention will be understood more fully from the detailed description given below and from the accompanying drawings of various embodiments of the invention. The drawings, however, should not be taken to limit the invention to the specific embodiments, but are for explanation and understanding only.

FIG. 1A illustrates a block diagram of one embodiment of a computer system;

FIG. 1B illustrates a block diagram of another embodiment of a computer system;

FIG. 2 illustrates a block diagram of a conventional platform implementation of multiple PCIe connectors;

FIG. 3 illustrates a block diagram of one embodiment of a platform implementation of two PCIe connectors operating in dual graphics card mode;

FIG. 4 illustrates a block diagram of one embodiment of a platform implementation of two PCIe connectors operating in single graphics card mode;

FIG. 5 illustrates a block diagram of one embodiment of a continuity module; and

FIG. 6 is a flow diagram depicting a method of one embodiment of the invention.

### DETAILED DESCRIPTION

A method and apparatus to enable Peripheral Component Interconnect Express (PCIe) connector multiplexing are presented. Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

In the following description, numerous details are set forth. It will be apparent, however, to one skilled in the art, that the embodiments of the invention may be practiced without these specific details. In other instances, well-known structures and devices are shown in block diagram form, rather than in detail, in order to avoid obscuring the invention.

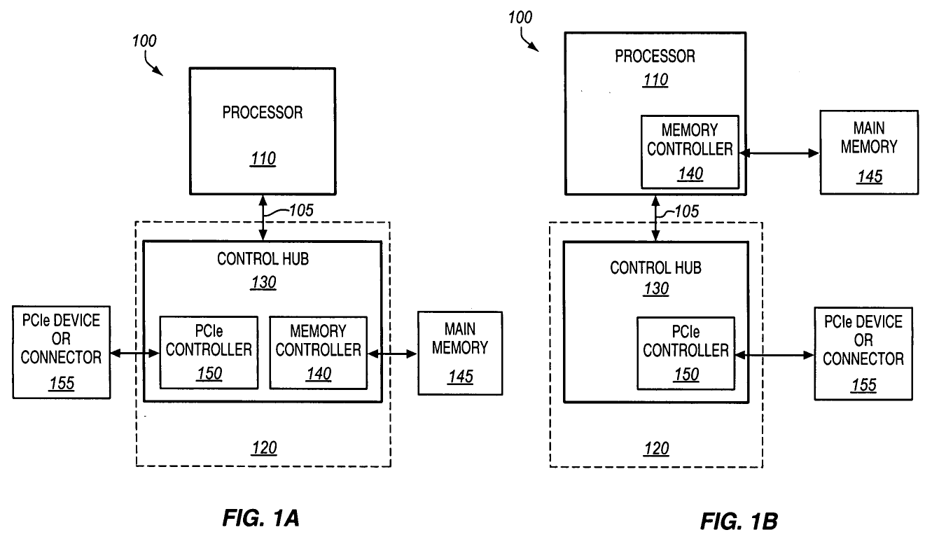

FIGS. 1A and 1B illustrate a block diagram of one embodiment of a computer system 100. Computer system 100 includes a processor 110 coupled to an interface 105. In some embodiments, the terms processor and central processing unit (CPU) may be used interchangeable. In one embodiment, processor 110 is a processor in the Pentium® family of processors including the Pentium® IV processors available from Intel Corporation of Santa Clara, Calif. Alternatively, other processors may be used. In a further embodiment, processor 110 may include multiple processor cores.

According to one embodiment, interconnect 105 communicates with a control hub 130 component of a chipset 120. In some embodiments, interconnect 105 may be point-to-point or, in other embodiments may be connected to more than one chip. Control hub 130 includes a memory controller 140 that is coupled to a main system memory 145, as depicted in FIG. 1A. In other embodiments, memory controller 140 may be in the same chip as processor 110, as depicted in FIG. 1B.

In some embodiments, the memory controller 140 may work for all cores or processors in the chip. In other embodiments, the memory controller 140 may include different portions that may work separately for different cores or processors in the chip.

Main system memory 145 stores data and sequences of instructions and code represented by data signals that may be executed by processor 110 or any other device included in computer system 100. In one embodiment, main system memory 145 includes dynamic random access memory (DRAM); however, main system memory 145 may be implemented using other memory types. According to one embodiment, control hub 130 also provides an interface to input/output (I/O) devices within computer system 100. For example, in one embodiment, control hub 130 may include a PCIe controller 150 to communicate with a PCIe device or connector 155. In some embodiments, the PCIe controller 150 may be architecturally disposed in a different location in the computer system 100 than shown here.

The following description will describe embodiments of the invention with reference to dual PCIe connectors. However, one skilled in the art will appreciate that other connectors may utilize the various embodiments of the invention. Also, it is envisioned that various embodiments may be expanded to apply to more than two PCIe connectors. Additionally, the following description describes embodiments of the invention in terms of graphics cards, one skilled in the art will appreciate that other types of connections may be utilized in lieu of graphics cards. It is envisioned that embodiments of the invention may be expanded to future revisions and generations of PCIe specifications and devices.

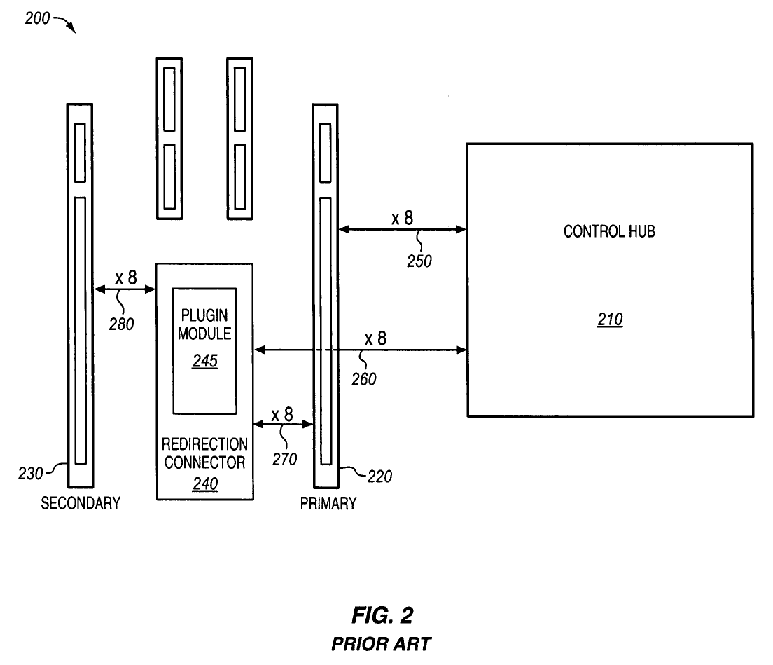

FIG. 2 is a block diagram illustrating a conventional solution to enable a dual graphic card configuration. System 200 includes a controller hub with a PCIe interface 210, primary connector 220, secondary connector 230, redirection connector 240, plug-in module 245, and data lanes 250-280. One or more graphic cards may be connected into either of connectors 220 and 230. In one embodiment, connectors 220 and 230 are PCIe connectors.

Redirection connector 240 and plug-in module 245 enable system 200 to operate in either single graphic card mode or dual graphic card mode. Redirection connector 240 and plug-in module 245 together are implemented as a separate unit on the motherboard. In a single graphic card mode, a graphic card is plugged into the primary connector 220 and then all data for the card is routed through lanes 250, 260, and 270. When plug-in module 245 is inserted into redirection connector 240, the redirection connector 240 redirects data sent from lanes 260 to the graphic card in primary connector 220 through lanes 270 via the plug-in module 245. Therefore, the single graphic card in the primary connector slot 220 receives all of its data via lanes 250, 260 and 270. This allows the highest data-bandwidth to be sent to the single graphic card.

In a dual graphic card mode, two graphic cards are each plugged into the primary connector 220 and the secondary connector 230. All data for these cards is then routed through lanes 250, 260, and 280. The first graphics card in the primary connector slot 220 receives all of its data through lanes 250. The second graphic card in the secondary connector slot 230 receives its data via lanes 260 and 280. Plug-in module 245, when inserted into redirection connector 240, ensures that data sent from lane 260 is redirected to the secondary connector 230 via lanes 280 via the plug-in module 245. This results in ½ of the available PCIe bandwidth available from the chipset to each of the graphic cards, but improved graphics capabilities are possible as multiple cards may be utilized. However, redirection connector 240 and plug-in module 245 may be costly to produce as it requires putting a new connector down in combination with the cost of the plug-in module, as well as occupying valuable space on the motherboard.

Embodiments of the invention utilize hardware to enable PCIe connector multiplexing utilizing existing platform components on the motherboard. Embodiments of the invention enable such an implementation through a cost-effective platform solution using a PCIe continuity module. In one embodiment, this platform multiplexing implementation enables dual graphic card functionality with a chipset that supports a bifurcated PCIe interface.

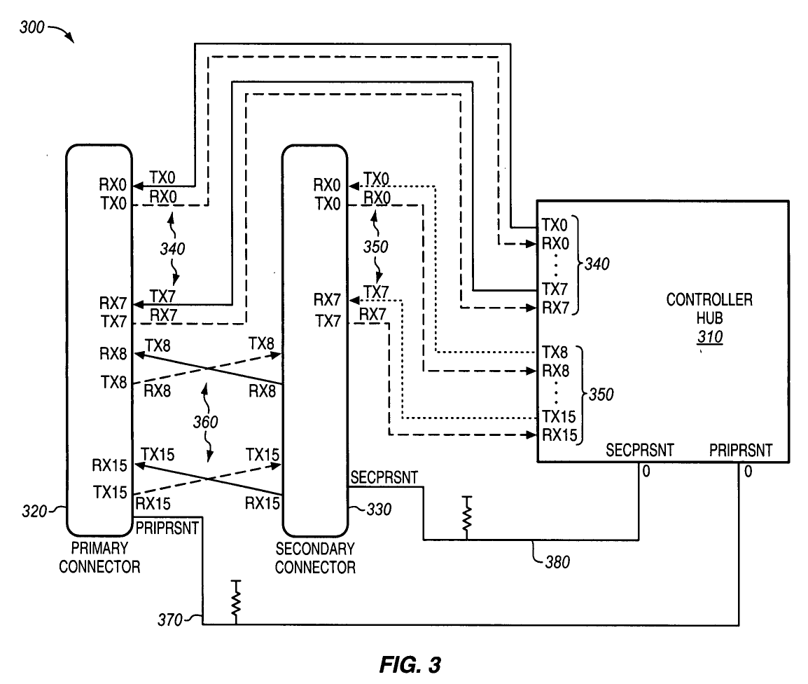

FIG. 3 is a block diagram illustrating one embodiment of the invention. System 300 depicts a platform implementation of two PCIe connectors operating in dual graphic card mode. It should be noted that this capability is not limited to just a dual graphic card configuration, however the description here will focus on the dual graphic card system configuration example. System 300 includes a controller hub 310, primary PCIe connector 320, secondary PCIe connector 330, PCIe lanes 340-360, primary present signal 370, and secondary present signal 380.

As illustrated in FIG. 3, embodiments of the invention include a platform PCIe connection pattern and PCIe connector placement pattern. The PCIe interface off the chipset is split up and connected to two connectors, primary PCIe connector 320 and secondary PCIe connector 330. Lower PCIe lanes 340 are connected to the primary PCIe connector 320, and upper PCIe lanes 350 are connected to the secondary connector 330. The lane numbering (e.g., RX0, TX0 . . . RX7, TX8, etc.) within the connectors 320, 330 represents the actual signals/port assignment for the device inserted into the PCIe connector 320, 330. The lane numbering on the outside of the connectors 320, 330 represents the physical pin names/port numbers of the PCIe connectors 320, 330 per the connector specification.

In one embodiment, data communication between the two graphic cards when in dual graphic card mode is enabled by allowing the graphic cards to communicate graphics data directly between the cards without having to first travel through the controller hub. PCIe lanes 360 interconnect the primary and secondary connectors 320, 330 to enable communicative abilities between the two connectors. The transmit signal lanes from primary connector 320 may be connected to the receive signal lanes of secondary connector 330, and vice versa. PCIe lanes 360 may then be utilized to enable direct communication between two graphics cards without having to arbitrate for bandwidth with the controller hub 310 and tie up other PCIe lanes, such as upper and lower PCIe lanes 340, 350.

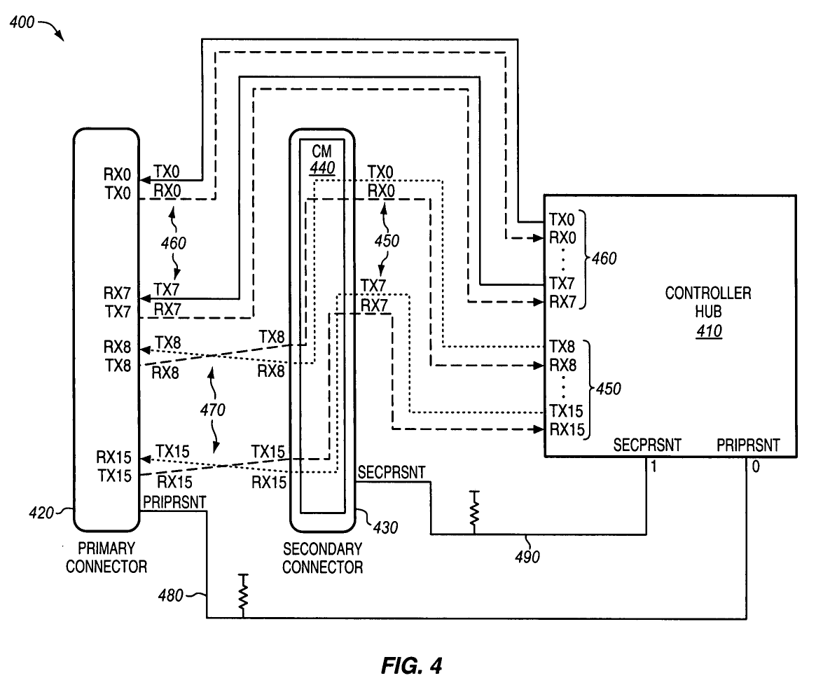

FIG. 4 is a block diagram illustrating another embodiment of the invention. System 400 depicts a platform implementation of two PCIe connectors operating in single graphic card mode. System 400 implements the same PCIe connection and connector placement configuration as system 300, however it further illustrates the use of a PCIe continuity module 440. System 400 includes controller hub 410, primary PCIe connector 420, secondary PCIe connector 430, continuity module 440, PCIe lanes 450-470, primary present signal 480, and secondary present signal 490.

The continuity module 440 is responsible for bridging the upper PCIe lanes 450 to the primary connector 420 through PCIe lanes 470. Therefore, the PCIe lanes 450 coupled to the controller hub 410 are connected to the primary connector 420 when the continuity module 440 is plugged into the secondary connector slot 430. This provides the full data transfer capability to the primary connector 420 when a single graphic card is used in the system 400. When a second graphic card is desired in system 400, the second graphic card may replace continuity module 440, as illustrated in FIG. 3.

In one embodiment, when the continuity module 440 is removed from the system 400, the controller hub 410 may be informed when the platform is configured for single or dual graphic card configuration. To inform the controller hub 410 of the platform configuration (single or dual graphic card mode), primary present signal 480 from the primary PCIe connector 420 and secondary present signal 490 from the secondary PCIe connector 430 send signals to the controller hub 410. These signals 480, 490 are generated by a present detect pin in each PCIe connector 420, 430 that indicates when a graphic card is present in the PCIe connectors 420, 430.

In one embodiment, the signals 480, 490 may be implemented with pull-up or pull-down resistors. When a graphic card is inserted into the PCIe connector 420, 430, the signal is pulled low. A logic ‘0’ value on this signal informs the controller hub 410 that a graphic card is inserted in the PCIe connector 420, 430. When a graphic card is not present, the signal is pulled high. A logic ‘1’ value on this signal informs the controller hub 410 that a graphic card is not inserted in the PCIe connector 420, 430. The controller hub 410 may then determine, based on the signals 480, 490, whether the system is operating in dual graphic card mode (i.e., both signals pulled low), or in single graphic card mode (i.e., one signal pulled low, one signal pulled high).

With reference to FIG. 3, primary present signal 370 is a logic value ‘0’ indicating that a graphic card is inserted in the primary connector slot 320, and secondary present signal 380 is also a logic value ‘0’ indicating that a graphic card is inserted in the secondary connector slot 330. Controller hub 310 may then determine that the system 300 is operating in dual graphic card mode. Referring to FIG. 4, primary present signal 480 is a logic value ‘0’ indicating a graphic card is inserted in the primary connector slot 420, while secondary present signal 490 is a logic value ‘1’ indicating that a graphic card is not inserted into the secondary connector slot 430. Controller hub 410 may then determine that the system 400 is operating in single graphic card mode.

In one embodiment, the platform configuration described with respect to FIGS. 3 and 4 enables support of a bifurcated PCIe ×16 interface. The ×16 interface off of the controller hub is split between the primary and secondary connectors. The continuity module enables one of the connectors to operate with ×16 functionality. When the continuity module is removed it enables the interface to operate with a dual ×8 functionality.

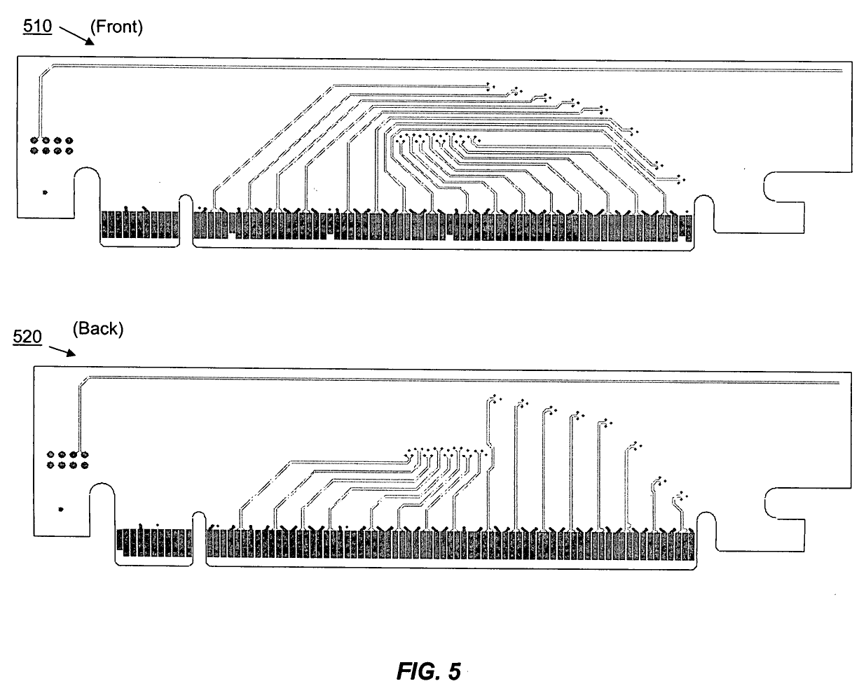

FIG. 5 illustrates an embodiment of the continuity module. The front 510 and back 520 views of a continuity module are depicted. In one embodiment, continuity module 510, 520 is the same as continuity module 440 depicted and described with respect to FIG. 4. Continuity module 510, 520 is able to leverage the existing architecture of a PCIe interface and controller hub to support both dual graphic card functionality and single graphic card functionality. In other embodiments, the continuity module 510, 520 may enable multiplexing between more than two PCIe connector slots.

In one embodiment, the continuity module 510, 520 may include electrical connections, such as wire traces, to complete the connections between the PCIe lanes coupled to a PCIe connector. As illustrated, the traces connect the pins at the upper part of the connector to the pins at the lower part of the connector. One skilled in the art will appreciate that other embodiments of the continuity module may also accomplish the same results.

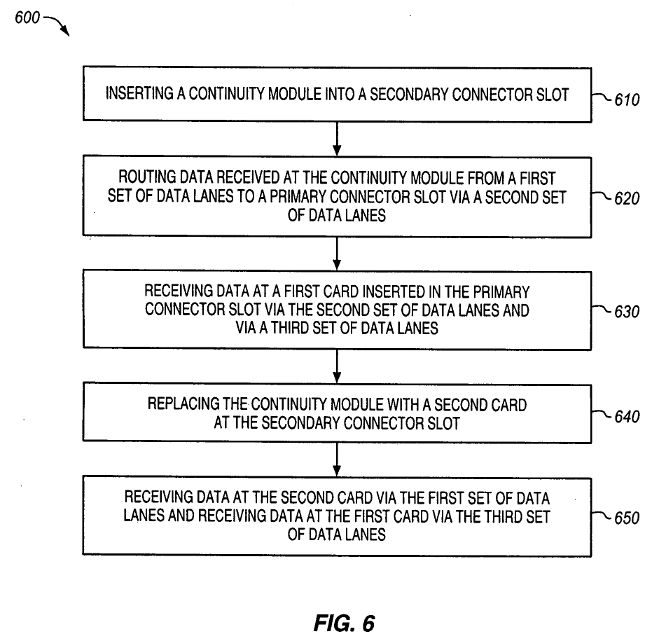

FIG. 6 is a flow diagram illustrating a method of one embodiment of the invention. Method 600 begins at processing block 610 where a continuity module is inserted into a secondary PCIe connector slot. In one embodiment, the continuity module may be the same as continuity module 440 described with respect to FIG. 4. At processing block 620, the continuity module routes data received from a first set of data lanes to a primary PCIe connector slot via a second set of data lanes.

Then, at processing block 630, a first card inserted in the primary PCIe connector slot receives data via the second set of data lanes from the continuity module and via a third set of data lanes. At processing block 640, the continuity module is replaced with a second card at the secondary PCIe connector slot. The second card may then receive data via the first set of data lanes, while the first card receives data via the third set of data lanes, at processing block 650.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the invention.

What is claimed is:

1. An apparatus, comprising a continuity module to insert into a first Peripheral Component Interconnect Express (PCIe) connector slot and to route a first set of data lanes coupled to the first PCIe connector slot to a second set of data lanes coupled to both of the first PCIe connector slot and a second PCIe connector slot.

2. The apparatus of claim 1, further comprising a first card having a connector portion adapted to be inserted into the second PCIe connector slot, the first card to receive data via both of the second set of data lanes and a third set of data lanes.

3. The apparatus of claim 2, wherein the first and third set of data lanes are directly coupled to a controller hub that controls the data throughput to the first and second PCIe connector slots.

4. The apparatus of claim 1, wherein the first and second PCIe connector slots are configured to produce a signal to indicate when a graphic card is present in each of the first and second PCIe connector slots.

5. The apparatus of claim 1, wherein the continuity module includes electrical lines adapted to connect the first set of data lanes at an upper part of the first PCIe connector slot to the second set of data lanes at a lower part of the first PCIe connector slot.

6. The apparatus of claim 2, further comprising a second card having a connector portion adapted to be inserted into the first PCIe connector slot in lieu of the continuity module and to receive data via the first set of data lanes.

7. The apparatus of claim 6, wherein the second set of data lanes are configured to allow the first and second cards to directly communicate with each other.

8. The apparatus of claim 2, wherein the first and second cards and the first, second, and third sets of data lanes are PCIe compatible.

9. The apparatus of claim 6, wherein the first and second cards are graphic cards.

10. A method, comprising:
routing data received at a continuity module inserted into a secondary Peripheral Component Interconnect Express (PCIe) connector slot from a first set of data lanes to a primary PCIe connector slot via a second set of data lanes; and
receiving data at a first card inserted into the primary PCIe connector slot via the second set of data lanes and via a third set of data lanes.

11. The method of claim 10, further comprising replacing the continuity module with a second card at the secondary PCIe connector slot, wherein the second card receives data via the first set of data lanes while the first card receives data via the third set of data lanes.

12. The method of claim 11, wherein the first card and the second card communicate directly via the second set of data lanes.

13. The method of claim 12, wherein the first and second cards and the first, second, and third sets of data lanes are PCIe compatible.

14. The method of claim 10, further comprising producing signals at both of the primary and secondary PCIe connector slots to indicate when a graphic card is present in each of the primary and secondary PCIe connector slots.

15. A system, comprising:
a video device;
a controller hub coupled to the video device;
a plurality of Peripheral Component Interconnect Express (PCIe) connector slots communicatively coupled to the controller hub to receive a card; and
a continuity module to insert into a first PCIe connector slot of the plurality of PCIe connector slots and to route a first set of data lines coupled to the first PCIe connector slot to a second set of data lines coupled to both of the first PCIE connector slot and a second PCIe connector slot of the plurality of PCIe connector slots.

16. The system of claim 15, further comprising a first card having a connector portion adapted to insert into the second PCIe connector slot, the first card to receive data via both of the second set of data lanes and a third set of data lanes.

17. The system of claim 16, wherein the first and second PCIe connector slots are configured to produce a signal to indicate when a graphic card is present in each of the first and second PCIe connector slots.

18. The system of claim 17, further comprising a second card having a connector portion adapted to insert into the first PCIe connector slot in lieu of the continuity module and to receive data via the first set of data lanes.

19. The system of claim 18, wherein the second set of data lanes are configured to allow the first and second cards to directly communicate with each other.

20. The system of claim 16, wherein the first and second cards and the first, second, and third sets of data lanes are PCIe compatible, and the first and second cards are graphics cards.
